(19) United States
(12) Patent Application Publication
(10) Pub. No.: US 2024/0395627 A1
(43) Pub. Date: Nov. 28, 2024

(54) GRAPHENE LAYER FOR LOW RESISTANCE CONTACTS AND DAMASCENE INTERCONNECTS

(71) Applicant: TAIWAN SEMICONDUCTOR MANUFACTURING COMPANY, LTD., Hsinchu (TW)

(72) Inventors: Mrunal Abhijith KHADERBAD, Hsinchu (TW); Wei-Yen WOON, Hsinchu (TW); Cheng-Ming LIN, Kaohsiung (TW); Han-Yu LIN, Nantou (TW); Szu-Hua CHEN, Hsinchu (TW); Jhih-Rong HUANG, Zhubei (TW); Tzer-Min SHEN, Hsinchu (TW)

(73) Assignee: TAIWAN SEMICONDUCTOR MANUFACTURING COMPANY, LTD., Hsinchu (TW)

(21) Appl. No.: 18/791,021

(22) Filed: Jul. 31, 2024

Related U.S. Application Data
(62) Division of application No. 17/550,670, filed on Dec. 14, 2021.
(60) Provisional application No. 63/157,517, filed on Mar. 5, 2021.

(51) Int. Cl. H01L 21/8234; H01L 21/48; H01L 21/768; H01L 29/417; H01L 29/66; H01L 29/78

(52) U.S. Cl. CPC H01L 21/823431; H01L 21/486; H01L 21/76871; H01L 29/41791; H01L 29/66795; H01L 29/785

(57) ABSTRACT

The present disclosure provides low resistance contacts and damascene interconnects with one or more graphene layers in fin structures of finFETs. An example semiconductor device can include a substrate with a fin structure that includes an epitaxial region. The semiconductor device can also include an etch stop layer on the epitaxial region, and an interlayer dielectric layer on the etch stop layer. The semiconductor device can further include a metal contact, above the epitaxial region, formed through the etch stop layer and the interlayer dielectric layer, and a graphene film at interfaces between the metal contact and each of the epitaxial region, the etch stop layer, and the interlayer dielectric layer.

### CROSS-REFERENCE TO RELATED APPLICATIONS

This application is a divisional application of U.S. Non-Provisional application Ser. No. 17/550,670, titled “Graphene Layer for Low Resistance Contacts and Damascene Interconnects,” filed on Dec. 14, 2021, which claims benefit of U.S. Provisional Patent Application No. 63/157,517, titled “Method of Graphene Insertion for Low Resistance Contacts and Damascene Interconnects,” filed on Mar. 5, 2021, which are incorporated herein by reference in their entireties.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs and finFETs. Such scaling down has increased the complexity of semiconductor manufacturing processes.

### BRIEF DESCRIPTION OF THE DRAWINGS

Aspects of this disclosure are best understood from the following detailed description when read with the accompanying figures. It is noted that, in accordance with the common practice in the industry, various features are not drawn to scale. In fact, the dimensions of the various features may be arbitrarily increased or reduced for clarity of discussion.

FIG. 1 is an isometric view of exemplary finFETs, in accordance with some embodiments of the present disclosure.

FIG. 2 is a cross-sectional view of exemplary finFETs, in accordance with some embodiments of the present disclosure.

FIG. 3 is a cross-sectional view of exemplary finFETs, in accordance with some embodiments of the present disclosure.

FIG. 4 is a cross-sectional view of exemplary finFETs, in accordance with some embodiments of the present disclosure.

FIG. 5 is a flow diagram of an exemplary method for inserting a graphene film for a contact in a finFET, in accordance with some embodiments of the present disclosure.

FIGS. 6A-6D are cross-sectional views of a portion of an exemplary finFET at certain fabricating stages of the method shown in FIG. 5, in accordance with some embodiments of the present disclosure.

FIG. 7 is a flow diagram of an exemplary method for inserting a graphene film for a contact in a finFET, in accordance with some embodiments of the present disclosure.

FIGS. 8A-8C are cross-sectional views of a portion of an exemplary finFET at certain fabricating stages of the method shown in FIG. 7, in accordance with some embodiments of the present disclosure.

FIG. 9 is a flow diagram of an exemplary method for inserting a graphene film for a contact in a finFET, in accordance with some embodiments of the present disclosure.

FIGS. 10A-10D are cross-sectional views of a portion of an exemplary finFET at certain fabricating stages of the method shown in FIG. 9, in accordance with some embodiments of the present disclosure.

FIG. 11 is a flow diagram of an exemplary method for inserting a graphene film for a contact in a finFET, in accordance with some embodiments of the present disclosure.

FIGS. 12A-12D are cross-sectional views of a portion of an exemplary finFET at certain fabricating stages of the method shown in FIG. 11, in accordance with some embodiments of the present disclosure.

FIG. 13 is a flow diagram of an exemplary method for inserting a graphene film for a contact in a finFET, in accordance with some embodiments of the present disclosure.

FIGS. 14A-14D are cross-sectional views of a portion of an exemplary finFET at certain fabricating stages of the method shown in FIG. 13, in accordance with some embodiments of the present disclosure.

FIG. 15 is a flow diagram of an exemplary method for inserting a graphene film for a contact in a finFET, in accordance with some embodiments of the present disclosure.

FIGS. 16A-16C are cross-sectional views of a portion of an exemplary finFET at certain fabricating stages of the method shown in FIG. 15, in accordance with some embodiments of the present disclosure.

FIG. 17 is a flow diagram of an exemplary method for forming an interconnect structure of a finFET, in accordance with some embodiments of the present disclosure.

FIG. 18 is a cross-sectional view of an exemplary interconnect structure of a finFET formed by the method shown in FIG. 17, in accordance with some embodiments of the present disclosure.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5% of the value (e.g., ±1%, ±2%, ±3%, ±4%, ±5% of the value). These values are merely examples and are not intended to be limiting. The terms “about” and “substantially” can refer to a percentage of the values as interpreted by those skilled in relevant art(s) in light of the teachings herein.

As semiconductor devices shrink to smaller die size to reduce manufacturing cost and increase transistor density, low resistance in contacts and interconnects becomes a critical factor for device performance. Due to aggressive scaling of critical dimensions and using barrier layers, resistivity performance is impacted by contact resistivity between source/drain (S/D) epitaxial layer (EPI) to silicide, liner resistivity, and surface scattering effect. S/D contact resistivity, contact plug resistance, via, and interconnect resistance have become critical in advanced nodes (e.g., 5 nm process node size, 2 nm process node size, and other process node sizes).

Titanium silicide (TiSiₓ) can be used in the formation of n-type FET (NFET) and p-type FET (PFET). Since the work function of TiSiₓ is close to Si mid-gap, the use of TiSiₓ can result in a higher contact resistance. To reduce the Schottky barrier height (SBH), dual silicides—instead of TiSiₓ—can be used, but there is no manufacturing solution for a thermally stable n-type silicide on n-type epitaxial layer or p-type silicide on p-type epitaxial layer. Further, nitride materials (e.g., titanium nitride (TiN) and tantalum nitride (TaN)) can be used as liners and barriers of the metal vias/interconnects to suppress metal diffusion to the dielectric, which further increases the parasitic resistance and/or interconnect resistance with scaling.

This disclosure provides exemplary epitaxial low resistance contacts and damascene interconnects with one or more graphene (Gr) layers in fin structures of finFETs. This disclosure also provides exemplary methods for inserting Gr layers in interconnects, S/D contacts, and metal vias in middle-end-of-line (MEOL), and in back-end-of-line (BEOL) to achieve lower contact resistivity and a thinner liner and barrier. For example, a Gr layer can be inserted between an interconnect metal and S/D EPI to lower SBH and reduce surface scattering by metal encapsulation in the Gr layer. As another example, a Gr layer can be inserted between an interconnect metal and interlayer dielectric (ILD) or low-k dielectric to act as a barrier and/or a liner with a reduced thickness. This disclosure further provides exemplary low temperature catalyst process for Gr growth on dielectrics and EPI.

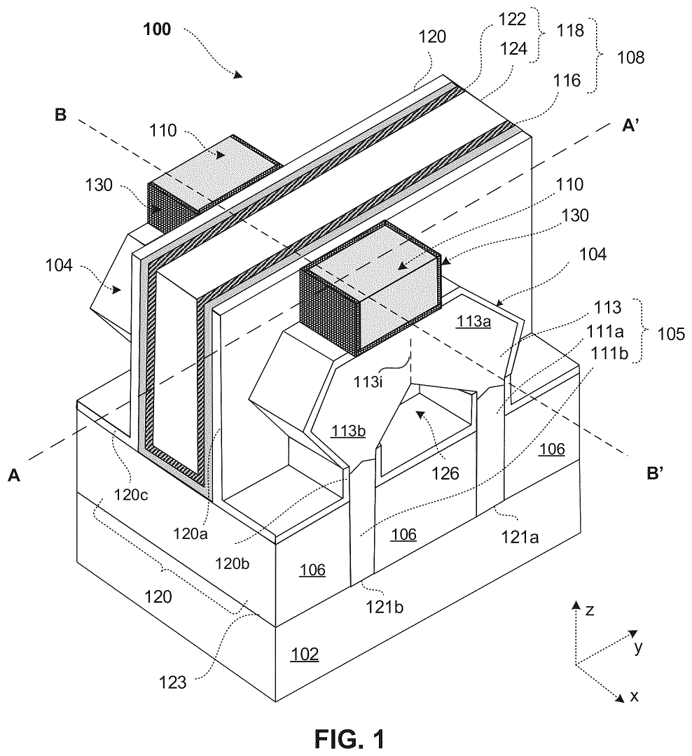

FIG. 1 is an isometric view of an exemplary finFET 100 in an integrated circuit after a gate replacement process. FIG. 1 is for illustrative purposes and is not drawn to scale. FinFET 100 includes a fin structure 104 formed on a substrate 102, shallow trench isolation (STI) regions 106, a gate structure 108 disposed on fin structure 104, S/D contacts 110, and spacer 120. FIG. 1 is taken after formation of gate structure 108 in a gate replacement process. FIG. 1 shows one gate structure 108. However, there may be additional gate structure(s) (not shown) similar and parallel to gate structure 108. In addition, finFET 100 may be incorporated into the integrated circuit through the use of other structural components, such as gate contacts, vias, interconnect metal layers, dielectric layers, and passivation layers, that are omitted for the sake of clarity.

Substrate 102 is a physical material on which finFETs 100 are formed. Substrate 102 includes a semiconductor material, such as, but not limited to, silicon, germanium, a compound semiconductor including silicon carbide, gallium arsenide, gallium phosphide, indium phosphide, indium arsenide, indium antimonide, an alloy including silicon germanium carbide, silicon germanium, gallium arsenic phosphide, gallium indium phosphide, gallium indium arsenide, gallium indium arsenic phosphide, aluminum indium arsenide, aluminum gallium arsenide, and a combination thereof. In some embodiments, substrate 102 includes a crystalline silicon substrate (e.g., a silicon wafer). In some embodiments, substrate 102 includes an epitaxial layer (EPI), and/or includes a silicon-on-insulator (SOI) structure. Further, substrate 102 may be doped with p-type dopants, such as boron, indium, aluminum, and gallium, or n-type dopants, such as phosphorus (P) and arsenic (As). The doped substrate 102 may be used for an n-type finFET, or alternatively used for a p-type finFET.

STI regions 106 provide electrical isolation of fin structure 104 from neighboring active and passive elements (not illustrated in FIG. 1) integrated with or deposited onto substrate 102. STI regions 106 are made of dielectric material. In some embodiments, STI regions 106 include silicon oxide, silicon nitride, silicon oxynitride, fluorine-doped silicate glass (FSG), a low-k dielectric material, and/or other suitable insulating material. In some embodiments, STI regions 106 include a multi-layer structure.

Gate structure 108 traverses fin structure 104. Fin structure 104 underlying gate structure 108 define the channel regions of finFETs 100. Gate structure 108 includes a gate electrode 118 and a dielectric layer 116 adjacent to and in contact with gate electrode 118. Gate structure 108 may further include capping layers, etch stop layers, and/or other suitable materials.

Dielectric layer 116 traverses fin structure 104. In some embodiments, dielectric layer 116 includes one or more layers of silicon oxide, silicon nitride, silicon oxynitride, or high-k dielectric materials, such as hafnium oxide (HfO₂), TiO₂, HfZrO, Ta₂O₃, HfSiO₄, ZrO₂, ZrSiO₂, and a combination thereof. As used herein, the term “high-k” refers to a high dielectric constant. In the field of semiconductor device structures and manufacturing processes, high-k refers to a dielectric constant that is greater than the dielectric constant of SiO₂ (e.g., greater than 3.9). Alternatively, high-k dielectric materials may include metal oxides. Examples of metal oxides used for high-k dielectrics include oxides of Li, Be, Mg, Ca, Sr, Sc, Y, Zr, Al, La, Ce, Pr, Nd, Sm, Eu, Gd, Tb, Dy, Ho, Er, Tm, Yb, Lu, and/or mixtures thereof. In some embodiments, dielectric layer 116 includes a single layer or a stack of insulating material layers. Dielectric layer 116 may be formed by chemical vapor deposition (CVD), atomic layer deposition (ALD), physical vapor deposition (PVD), e-beam evaporation, or other suitable process. Spacer 120 includes an insulating material, such as silicon oxide and silicon nitride, and protects the underlying regions during subsequent processing of the finFETs. Spacer 120 includes spacer portions 120a that form sidewalls of gate structure 108, spacer portions 120b that form sidewalls of fin structure 104, and spacer portions 120c that form protective layers on STI regions 106.

Gate electrode 118 may include a gate work function metal layer 122 and a gate metal fill layer 124. In some embodiments, gate work function metal layer 122 is disposed on dielectric layer 116. Gate work function metal layer 122 may include a single metal layer or a stack of metal layers. The stack of metal layers may include metals having work functions similar to or different from each other. In some embodiments, gate work function metal layer 122 includes any suitable material, such as aluminum (Al), copper (Cu), tungsten (W), titanium (Ti), tantalum (Ta), titanium nitride (TiN), tantalum nitride (TaN), nickel silicide (NiSi), cobalt silicide (CoSi), silver (Ag), tantalum carbide (TaC), tantalum silicon nitride (TaSiN), tantalum carbon nitride (TaCN), titanium aluminum (TiAl), titanium aluminum nitride (TiAlN), tungsten nitride (WN), metal alloys, and combinations thereof. Exemplary work function metal(s) that may be included in gate work function metal layer 122 in a p-type device include TiN, TaN, Ru, Mo, Al, WN, ZrSi₂, MoSi₂, TaSi₂, NiSi₂, WN, other suitable p-type work function metals, or combinations thereof. Exemplary work function metal(s) that may be included in work function metal layer 122 in an n-type device include Ti, Ag, TaAl, TaAlC, TiAlN, TaC, TaCN, TaSiN, Mn, Zr, other suitable n-type work function materials, or combinations thereof. Gate work function metal layer 122 may be formed using a suitable process, such as ALD, CVD, PVD, plating, and combinations thereof.

Gate metal fill layer 124 may include a single metal layer or a stack of metal layers. The stack of metal layers may include metals different from each other. In some embodiments, gate metal fill layer 124 includes any suitable conductive material, such as Ti, Ag, Al, TiAlN, TaC, TaCN, TaSiN, Mn, Zr, TiN, TaN, Ru, Mo, WN, Cu, W, Co, Ni, TiC, TiAlC, TaAlC, metal alloys, and combinations thereof. Gate metal fill layer 124 may be formed by ALD, PVD, CVD, or other suitable conductive material deposition process.

Fin structure 104 includes epitaxial regions (EPI) 105 disposed on both opposing sides of gate structure 108. Fin regions of fin structure 104 underlying gate structure 108 are regions formed from patterned portions of substrate 102 as described in detail below. EPIs 105 may form interfaces 121a and 121b with substrate 102 and interfaces (not shown) with regions of fin structure 104 underlying gate structure 108. In some embodiments, interfaces 121a and 121b are coplanar with interfaces 123 formed between STI regions 106 and substrate 102. In some embodiments, interfaces 121a and 121b are either above or below the level of interfaces 123.

EPIs 105 are configured to function as S/D regions of finFET 100 and include epitaxially-grown semiconductor material. In some embodiments, the epitaxially-grown semiconductor material is the same material as the material of substrate 102. In some embodiments, the epitaxially-grown semiconductor material includes a different material from the material of substrate 102 and imparts a strain on the channel regions underlying gate structure 108. The epitaxially-grown semiconductor material may include semiconductor material, such as germanium and silicon; compound semiconductor materials, such as gallium arsenide, and aluminum gallium arsenide; or a semiconductor alloy, such as silicon germanium and gallium arsenide phosphide.

In some embodiments, EPIs 105 are grown by CVD, e.g., low pressure chemical vapor deposition (LPCVD), atomic layer chemical vapor deposition (ALCVD), ultra-high vacuum chemical vapor deposition (UHVCVD), remote plasma chemical vapor deposition (RPCVD); molecular beam epitaxy (MBE) processes; any suitable epitaxial process; or any combinations thereof. In some embodiments, EPIs 105 are grown by an epitaxial deposition/partial etch process, which repeats the epitaxial deposition/partial etch process at least once. Such repeated deposition/partial etch process is also called a cyclic deposition-etch (CDE) process. In some embodiments, EPIs 105 are grown by selective epitaxial growth (SEG), where an etching gas is added to promote the selective growth of semiconductor material on the exposed surfaces of substrate 102, but not on insulating material (e.g., dielectric material of STI regions 106).

Further, EPIs 105 may be in-situ doped during the epitaxial growth process or by an ion implantation process after the epitaxial growth process. In some embodiments, EPIs 105 may be doped with p-type dopants, such as boron, indium, and gallium; n-type dopants, such as phosphorus and arsenic; and/or combinations thereof. SiGe EPIs 105 may be doped with p-type or n-type dopants, and/or combinations thereof. Si EPIs 105 may be doped with carbon and/or phosphorous. For p-type in-situ doping, p-type doping precursors, such as, but not limited to, diborane (B₂H₆) and boron trifluoride (BF₃), can be used. For n-type in-situ doping, n-type doping precursors, such as, but not limited to, PH₃ and AsH₃, can be used.

Each of EPIs 105 may include sub-regions 111a, 111b, 113a and 113b. Sub-regions 111a and 111b are epitaxially grown on different portions of substrate 102 and form respective interfaces 121a and 121b with substrate 102. As shown in FIG. 1, merged sub-region 113 may include portions 113a and 113b, which are epitaxially grown from respective unmerged sub-regions 111a and 111b and are merged at interface 113i. Fin structure 104 may be referred to as “a merged fin structure” because of its merged epitaxial portions 113a and 113b. In some embodiments, a top surface of EPIs 105 may be a (100) crystal plane of sub-regions 113.

Sub-regions 111a, 111b, 113a and 113b may be epitaxially grown under a pressure of about 10 Torr to about 300 Torr, at a temperature of about 500° C. to about 700° C. using reaction gases, such as hydrogen chloride (HCl) as an etching agent, germane (GeH₄) as a germanium (Ge) precursor, dichlorosilane (SiH₂Cl₂ or DCS) and/or silane (SiH₄) as a silicon (Si) precursor, B₂H₆ as boron (B) dopant precursor, hydrogen (H₂), and/or nitrogen (N₂). To achieve different concentrations of Ge in sub-regions 111a, 111b, 113a and 113b, the ratio of flow rate of Ge to Si precursors may be varied during their respective growth process.

Sub-regions 111a, 111b, 113a and 113b may have varying dopant concentration with respect to each other. For example, sub-regions 111a and 111b may be undoped or each may have a dopant concentration lower than the dopant concentrations of sub-regions 113a and 113b. In some embodiments, sub-regions 111a and 111b each have a dopant concentration less about 5×10²⁰ atoms/cm³, while sub-regions 113a and 113b have a dopant concentration in a range from about 1×10²⁰ atoms/cm³ to about 3×10²¹ atoms/cm³. In some embodiments, sub-regions 113a and 113b may have a gradient dopant concentration.

Also shown in FIG. 1, an insulating material (e.g., air) including void 126 is included within finFET 100. Void 126 may bound by portions of sub-regions 111a, 111b, 113a and 113b, STI region 106, and spacer 120. The cross-sectional profile of void 126 is not limited to the pentagon shape shown in FIG. 1, but may have any suitable geometric shape (e.g., circular, triangular, rectangular).

As shown in FIG. 1, S/D contacts 110 can be formed on the EPIs 105 and between S/D regions of finFET 100 and metal layers (not shown). Each S/D contact 110 can include a single metal layer or a stack of metal layers. The stack of metal layers may include metals different from each other. In some embodiments, S/D contact 110 includes any suitable conductive material, such as Co, W, Ru, Ti, Ag, Al, TiAlN, TaC, TaCN, TaSiN, Mn, Zr, TiN, TaN, Mo, WN, Cu, Ni, TiC, TiAlC, TaAlC, metal alloys, and combinations thereof. S/D contacts 110 may be formed by ALD, PVD, CVD, or other suitable conductive material deposition process.

A graphene (Gr) film 130 can be formed on a bottom surface and sidewalls of S/D contacts 110. By using Gr interface between S/D contacts (e.g., S/D contacts 110) and S/D regions (e.g., EPIs 105) of finFET 100, the S/D contact resistivity can be reduced by SBH tuning. Further, the Gr film 130 can act as a diffusion barrier to suppress metal diffusion from S/D contacts 110 to surrounding dielectric, and act as a high conductivity liner to reduce surface elastic scattering to further reduce S/D contact resistance. A thickness of Gr film 130 can be in a range from about 0.02 nm to about 2 nm, such as about 0.1 nm to about 1 nm. The thickness of Gr film 130 is much less than the thickness of ordinary Ta/TaN liner and/or barrier used in other devices, thus allows more volume for S/D contacts 110.

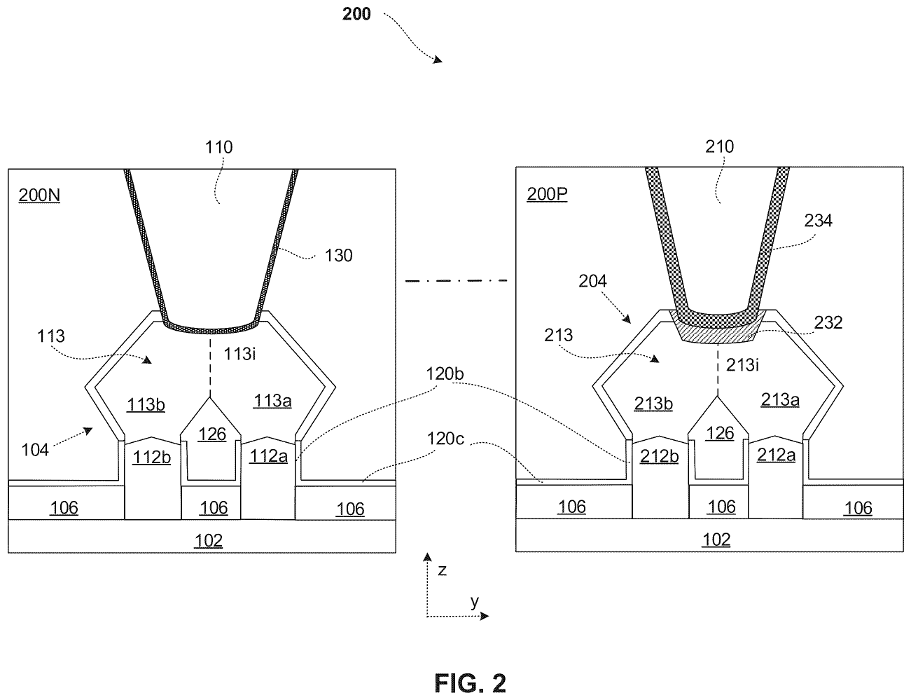

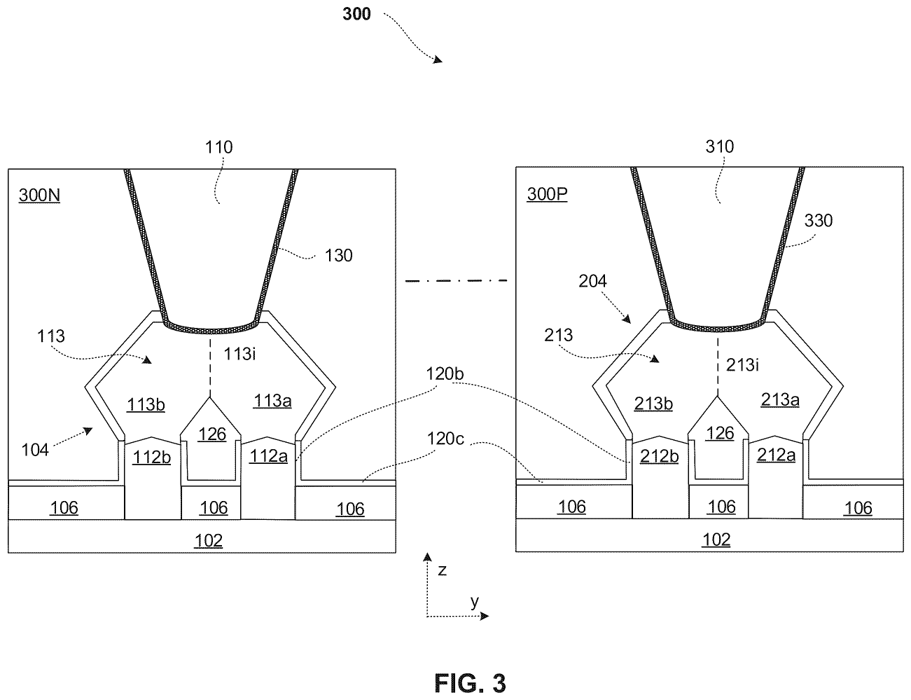

Graphene (Gr) film 130 can be used in either NFET or PFET or both NFET and PFET, according to some embodiments. FIGS. 2 and 3 illustrate two exemplary finFETs, in accordance with some embodiments of the present disclosure. Referring to FIG. 2, an NFET 200N and a PFET 200P are illustrated in a cross-sectional view along a line A-A′ as shown in FIG. 1. The NFET 200N is the same as the isometric view of finFET as shown in FIG. 1, in which EPI 113 can be a Si EPI doped with n-type type dopants (e.g., phosphorus and arsenic) and a Gr film 130 is formed on a bottom surface and sidewalls of S/D contact 110. PFET 200P includes EPI 213 (including sub-regions 212a, 212b, 213a, 213b, and interface 213i), which can be a SiGe EPI doped with p-type type dopants (e.g., boron, indium, and gallium). PFET 200P can further include a barrier 232 including p-type metal silicide (e.g., TiSiₓ) formed in a recess of EPI 213, and a liner 234 (e.g., TiN and TaN) formed on a bottom surface and sidewalls of S/D contact 210. In some embodiments, Gr film 130 may also be formed in PFET, while NFET uses silicide as the barrier and uses metal nitride as the liner. Referring to FIG. 3, both NFET 300N and PFET 300P include a Gr film 130/330 as a liner and/or a barrier.

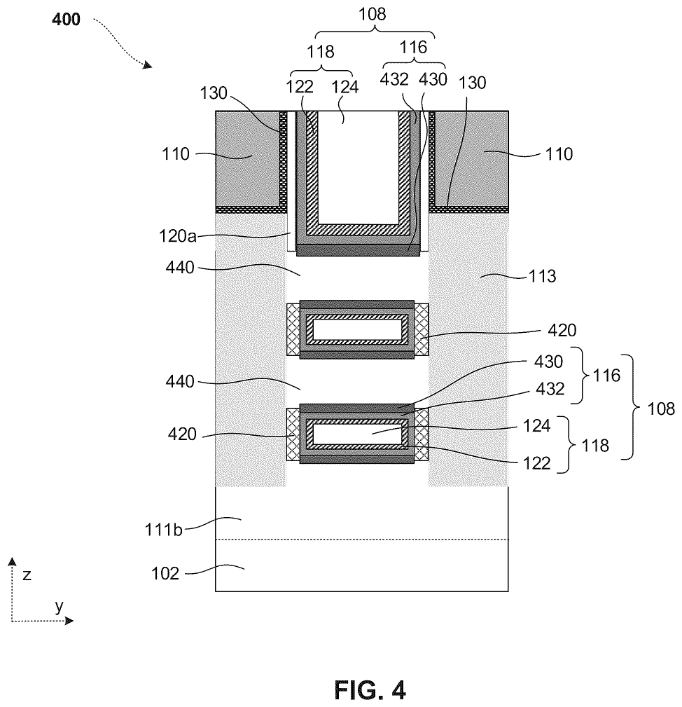

It is also noted that, the graphene (Gr) film 130 can be used in gate-all-around FETs (GAA-FETs). FIG. 4 is a cross-sectional view of exemplary GAA-FETs in accordance with some embodiments of the present disclosure. As shown in FIG. 4, channel structures 450 can be embedded in EPIs 413 and 423. Each channel structure 450 can include a channel layer 455 wrapped around by a gate dielectric layer 452. N-type GAA-FET 400N can include a Si EPI 413 doped with n-type type dopants (e.g., phosphorus and arsenic) and a Gr film 430 formed on a bottom surface and sidewalls of S/D contact 110. P-type GAA-FET 400P can include a SiGe EPI 423 doped with p-type type dopants (e.g., boron, indium, and gallium). PFET 200P can further include a barrier 432 including p-type metal silicide (e.g., TiSiₓ) formed in a recess of SiGe EPI 423, and a liner 434 (e.g., TiN, TaN) formed on a bottom surface and sidewalls of S/D contact 410. In some embodiments vice versa from FIG. 4, the Gr film 430 may also be formed in p-type GAA-FET only while n-type GAA-FET uses silicide as the barrier and uses metal nitride as the liner. In some embodiments not shown in the figures, both n-type GAA-FET and p-type GAA-FET can include a Gr film 430 as a liner and/or a barrier.

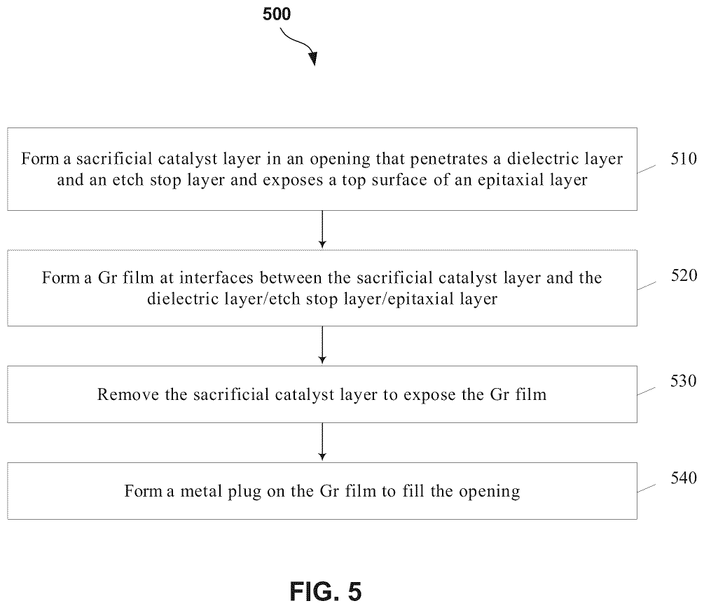

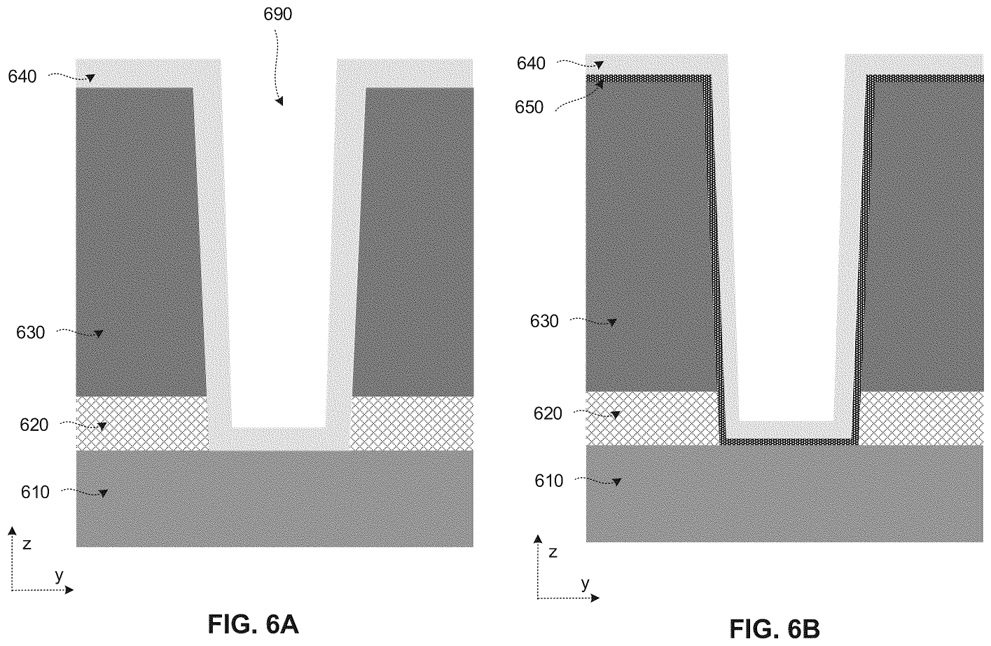

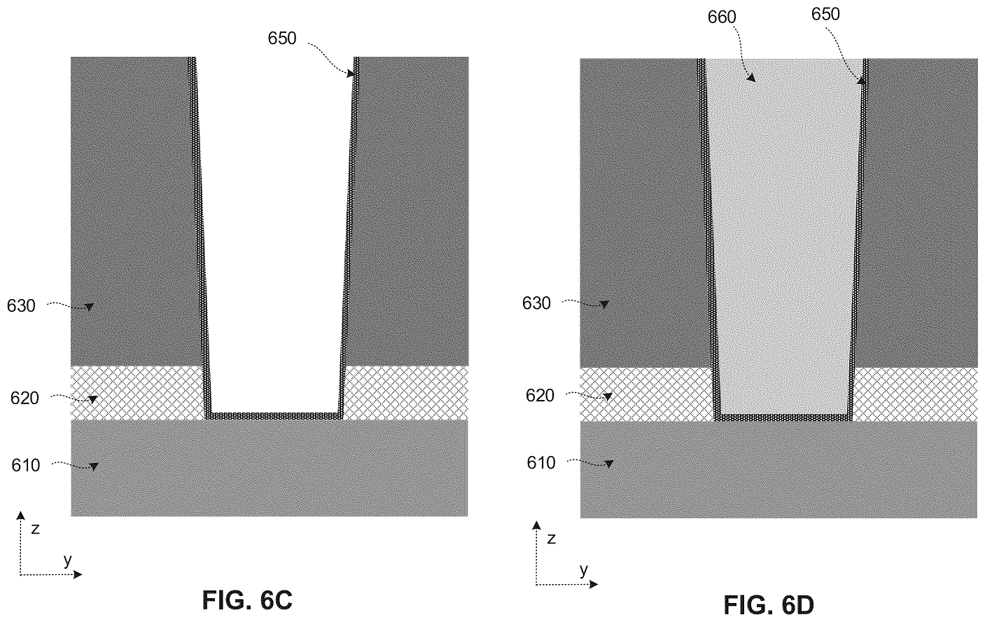

FIG. 5 is a flow diagram of an exemplary method 500 for inserting a Gr film for a contact in a finFET, in accordance with some embodiments of the present disclosure. FIGS. 6A-6D illustrate schematic cross-sectional views of a portion of an exemplary finFET at certain fabricating stages of the method shown in FIG. 5, according to some embodiments of the present disclosure. Method 500 does not produce completed finFET 100. Accordingly, it is understood that the operations shown in FIG. 5 are not exhaustive and that other operations can be performed before, after, or between any of the illustrated operations, and that some other processes may only be briefly described herein.

In operation 510, a sacrificial catalyst layer can be deposited in an opening that penetrates a dielectric layer and an etch stop layer and exposes a top surface of an epitaxial layer. The sacrificial catalyst layer can be used as a catalyst for graphene growth in a subsequent process.

In some embodiments, before operation 510, an epitaxial layer (EPI) 610 (e.g., EPIs 113 as shown in FIG. 1) can be epitaxially grown on a semiconductor material (e.g., substrate 102 as shown in FIG. 1). EPI 610 can be a Si EPI or a SiGe EPI. In some embodiments, EPI 610 is grown by CVD, e.g., LPCVD, ALCVD, UHVCVD, RPCVD, or MBE processes, or any other suitable epitaxial process or deposition/partial etch process. Further, EPI 610 can be in-situ doped during the epitaxial growth process or by an ion implantation process after the epitaxial growth process. For example, EPI 610 may be doped with p-type dopants (e.g., boron, indium, and gallium) or n-type dopants (e.g., phosphorus and arsenic). EPI 610 can function as S/D regions of the finFET.

In some embodiments, before operation 510, an etch stop layer (ESL) 620 can be formed on a top surface of EPI 610, and an ILD 630 can be formed on ESL 620. ESL 620 can prevent over-etching due to a non-uniform topography of the finFET from damaging the S/D regions of the finFET. ESL 620 can include a dielectric material that has a different etching rate than the material of EPI 610 and ILD 630, such as silicon nitride, silicon oxynitride, silicon carbide, and silicon carbonitride. ILD 630 may be formed of a dielectric material different from ESL 620, such as silica (SiO2), hafnium silicate (HfSiO4), zirconium silicate (ZrSiO4), phospho-silicate glass (PSG), boro-silicate glass (BSG), boron-doped phospho-silicate glass (BPSG), undoped silicate glass (USG), and any other suitable insulation materials. ILD 630 may be deposited by any suitable method, such as CVD, plasma-enhanced CVD (PECVD), and flowable CVD (FCVD).

In some embodiments, before operation 510, an opening 690 can be formed in ESL 620 and ILD 630 to expose a top surface of EPI 610. Opening 690 can be formed by any suitable patterning process. For example, a lithography process can be performed to pattern a mask for opening 690 and one or more subsequent wet or dry etching processes can be performed to etch a portion of ESL 620 and ILD 630 exposed by the patterned mask. A cleaning process, such as an ashing process and a strip process, can be performed after the etching to clean the sidewalls and bottom of opening 690.

As shown in FIG. 6A, a sacrificial catalyst layer 640 can be formed to cover the bottom surface and sidewalls of opening 690. In some embodiments, growing graphene in integrated circuits can bypass the process of transferring the graphene, another destructive process, from a growth catalyst to the device. Sacrificial catalyst layer 640 can include a metal material that is different from the metal material used to form a metal plug in a subsequent process. For example, sacrificial catalyst layer 640 can include Ni or any other suitable metal material, and can be formed by any suitable CVD or ALD. In some embodiments, a thickness of sacrificial catalyst layer 640 can be in a range from about 20 nm to about 80 nm. For example, a pure Ni catalyst layer can be deposited to a thickness less than about 50 nm.

In operation 520, a Gr film can be formed at the interfaces between the sacrificial catalyst layer and the dielectric layer/etch stop layer/epitaxial layer. In some embodiments, the Gr film can be formed by performing an inductively coupled plasma chemical vapor deposition (ICP CVD) process or using a solid or liquid drive in process. In one example using ICP CVD, a chamber can be pumped to a base pressure in a range from about 1×10⁻⁶ Torr to about 2×10⁻⁶ Torr using H₂ at a process temperature in a range from about 400° C. to about 450° C. After using Ar to purge the chamber and reestablishing the base pressure, acetylene (C₂H₂) can be flown at about 0.1 sccm bringing the chamber pressure to about 6×10 6 Torr. For plasma-enhanced growth, an activation anneal at an annealing temperature in a range from about 380° C. to about 450° C. (e.g., about 400° C.) can drive the deposited carbon atoms on the surface of the sacrificial catalyst layer 640 to be dissolved into the sacrificial catalyst layer 640, and to be precipitated and grown at the interfaces between the sacrificial catalyst layer 640 and EPI 610/ESL 620/ILD 630 to form Gr film 650, as shown in FIG. 6B. In some embodiments, a thickness of Gr film 650 can be in a range from about 0.02 nm to about 5 nm. Once the desired growth duration is reached (e.g., 7 min for CVD growth, 30 s for ICPCVD growth), C₂H₂ flow can be stopped, followed by another Ar purge to flush the remaining process gases out of the chamber. The chamber can then be cooled to room temperature.

In operation 530, the sacrificial catalyst layer can be removed to expose the Gr film. In some embodiments, a wet etching process can be performed to remove the sacrificial catalyst layer 640. In one example, when the sacrificial catalyst layer 640 is a pure Ni layer, FeCl₃ solution can be used to etch the Ni layer. A subsequent grinding process or chemical mechanical polishing (CMP) process can be performed to remove a portion of Gr film 650 outside of opening 690. As a result, the remaining portion of Gr film 650 attached on the bottom surface and sidewalls of the opening 690 can be exposed, as shown in FIG. 6C.

In operation 540, a metal plug can be formed on the Gr film to fill the opening. In some embodiments, the metal plug 660 can include a metal material different from the sacrificial catalyst layer 640, such as Co, W, and Ru. Metal plug 660 can be formed by any suitable deposition process, such as a CVD process with a process temperature in a range from about 130° C. to about 400° C., a process pressure in a range from about 100 Pa to about 1000 Pa, and a fas flow rate in a range from about 10 sccm to about 500 sccm. A subsequent CMP process can be performed to etch back the deposited metal plug to substantially coplanarize top surfaces of ILD 630, Gr film 650, and metal plug 660, as shown in FIG. 6D.

Method 500 (corresponding to FIGS. 5 and 6A-6D) is directed to a method for inserting a Gr film for a S/D contact as an example. Method 500 can be extendible to insert a Gr film for any suitable vias, such as those in a metal layer BEOL fill process.

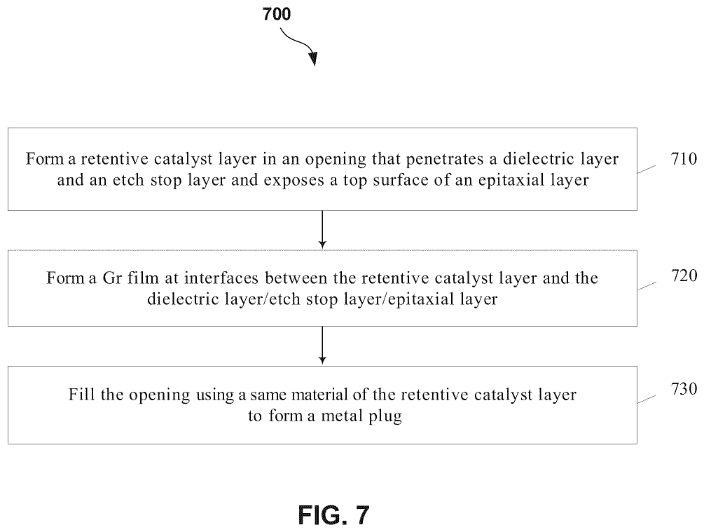

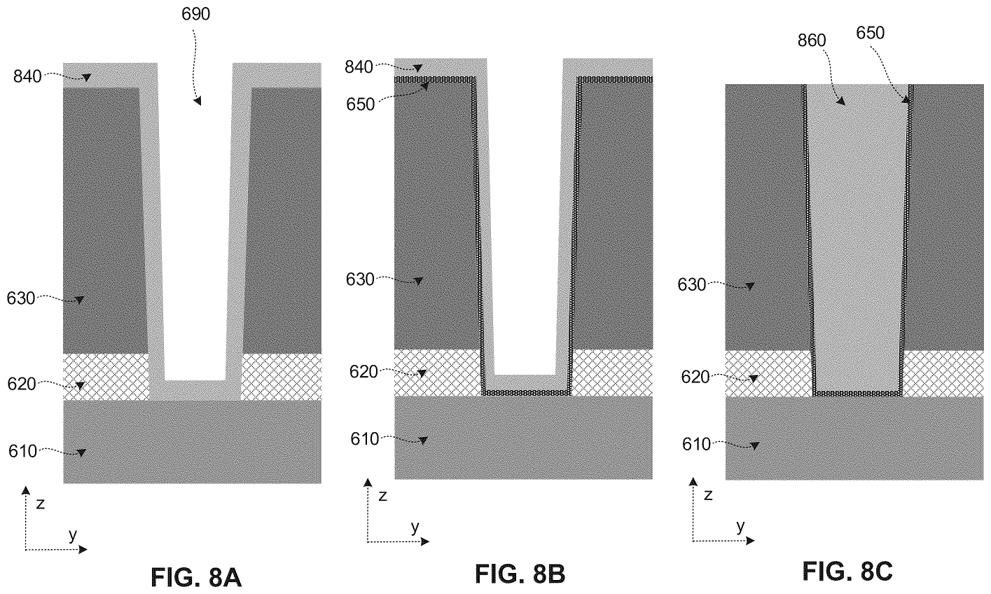

FIG. 7 is a flow diagram of another exemplary method 700 for inserting a Gr film for a contact in a finFET, in accordance with some embodiments of the present disclosure. FIGS. 8A-8C illustrate schematic cross-sectional views of a portion of an exemplary finFET at certain fabricating stages of the method shown in FIG. 7, according to some embodiments of the present disclosure. Method 700 does not produce completed finFET 100. Accordingly, it is understood that the operations shown in FIG. 7 are not exhaustive and that other operations can be performed before, after, or between any of the illustrated operations, and that some other processes may only be briefly described herein.

In operation 710, a retentive catalyst layer can be deposited in an opening that penetrates a dielectric layer and an etch stop layer and exposes a top surface of an epitaxial layer. The retentive catalyst layer can be used as a catalyst for graphene growth and as a seed layer for metal deposition in the subsequent operations.

Similar to method 500, in some embodiments, before operation 710, EPI 610 can be epitaxially grown on a semiconductor material, ESL 620 can be formed on a top surface of EPI 610, ILD 630 can be formed on ESL 620, and an opening 690 can be formed in ESL 620 and ILD 630 to expose a top surface of EPI 610. Different from operation 510, in operation 710, a retentive catalyst layer 840 can be formed to cover the bottom surface and sidewalls of the opening 690. Retentive catalyst layer 840 can include the same metal material as the metal plug in a subsequent process, such as Co, W, and Ru. A process of forming retentive catalyst layer 840 can be similar to the deposition of sacrificial catalyst layer 640, and be similar to operation 510 described above.

In operation 720, a Gr film can be formed at the interfaces between the retentive catalyst layer and the dielectric layer/etch stop layer/epitaxial layer. A process of forming Gr film 650 can be similar to operation 520 described above.

In operation 730, a metal plug can be formed on the retentive catalyst layer to fill the opening. Since retentive catalyst layer 840 can include the same metal material as the metal plug, it is not removed, as shown in FIG. 8B. A deposition process can be performed to fill the same metal material, such as Co, W, and Ru, into opening 690 to form metal plug 860. A subsequent CMP process can be performed to etch back the deposited metal plug to substantially coplanarize top surfaces of ILD 630, retentive catalyst layer 840, Gr film 650, and metal plug 860, as shown in FIG. 8C.

Method 700 (corresponding to FIGS. 7 and 8A-8C) is directed to a method for inserting a Gr film for a S/D contact as an example. Method 700 can be extendible to insert a Gr film for any suitable vias, such as those in a metal layer BEOL fill process.

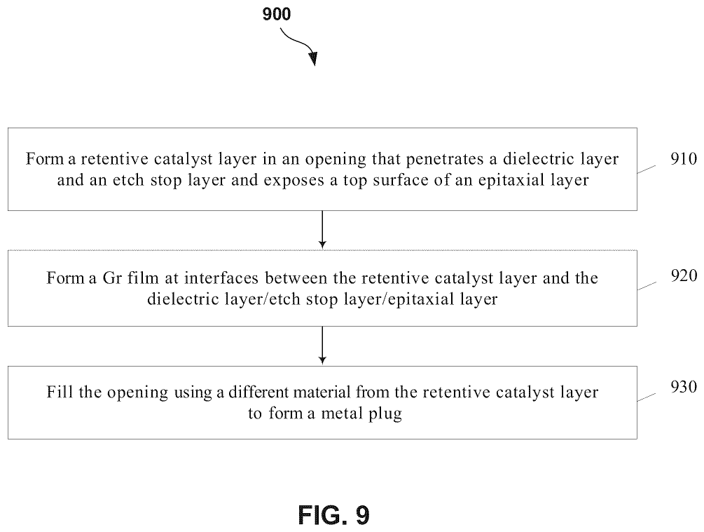

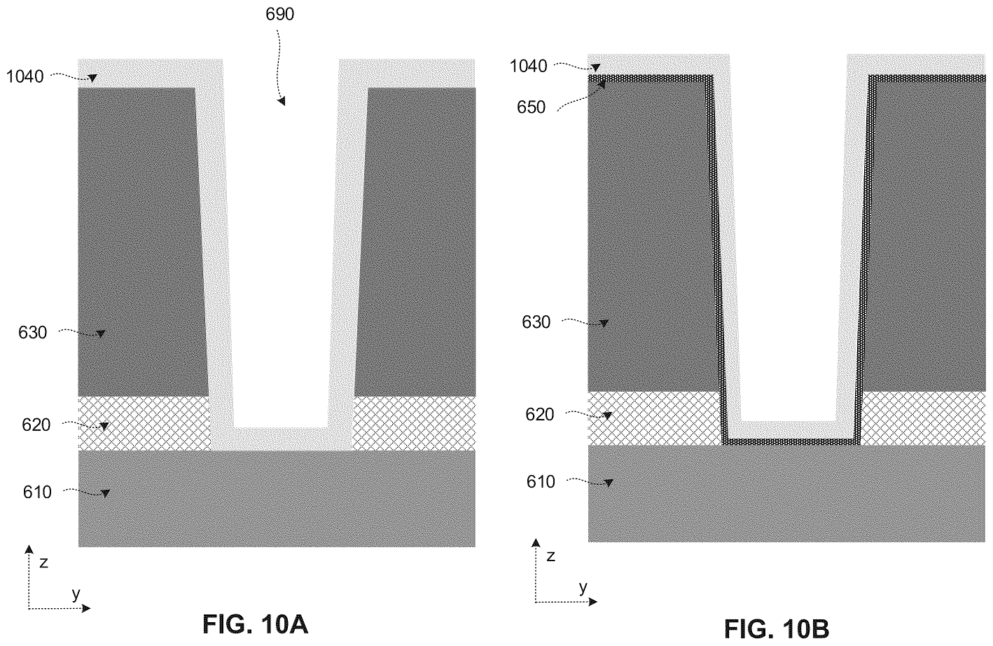

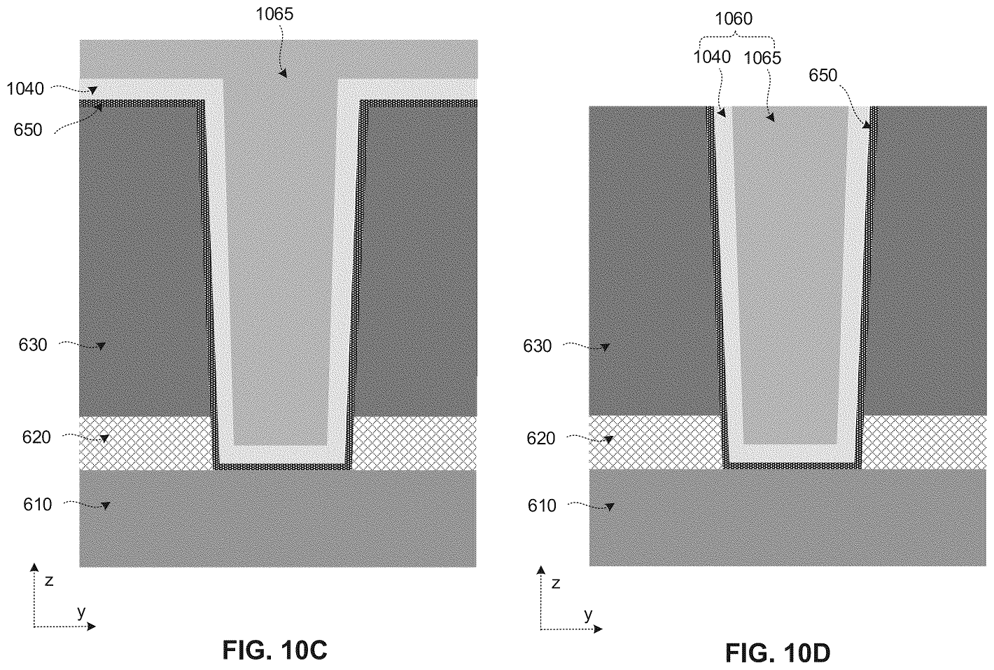

FIG. 9 is a flow diagram of another exemplary method 900 for inserting a Gr film for a contact in a finFET, in accordance with some embodiments of the present disclosure. FIGS. 10A-10D illustrate schematic cross-sectional views of a portion of an exemplary finFET at certain fabricating stages of the method shown in FIG. 9, according to some embodiments of the present disclosure. Method 900 does not produce completed finFET 100. Accordingly, it is understood that the operations shown in FIG. 9 are not exhaustive and that other operations can be performed before, after, or between any of the illustrated operations, and that some other processes may only be briefly described herein.

In operation 910, a retentive catalyst layer can be deposited in an opening that penetrates a dielectric layer and an etch stop layer and exposes a top surface of an epitaxial layer. The retentive catalyst layer can be used as a catalyst for graphene growth and as a seeding layer for metal deposition in subsequent processes.

Similar to method 700, in some embodiments, before operation 910, EPI 610 can be epitaxially grown on a semiconductor material, ESL 620 can be formed on a top surface of EPI 610, ILD 630 can be formed on ESL 620, and opening 690 can be formed in ESL 620 and ILD 630 to expose a top surface of EPI 610. In operation 910, a retentive catalyst layer 1040 can be formed to cover the bottom surface and sidewalls of the opening 690. Different from operation 710, retentive catalyst layer 1040 can include Ru or RuCo which can act as a liner. A process of forming retentive catalyst layer 1040 can be similar to the deposition of sacrificial catalyst layer 640, and be similar to operation 510 described above.

In operation 920, a Gr film can be formed at the interfaces between the retentive catalyst layer and the dielectric layer/etch stop layer/epitaxial layer. A process of forming Gr film 650 can be similar to operation 520 described above. During the annealing process, the Ru atoms and/or Co atoms in retentive seeding layer 1040 can be rearranged, which is referred as a coalescence process. The coalescence process can have three stages: the nucleation, the growth on account of dissolved matter, and the recondensation growth when the largest particles grow at dissolution of the smaller ones. During the first stage, the nuclei appear but do not grow in size. The decrease of the solution oversaturation during the nucleation initiates the second stage of the phase decomposition process. During the second stage, the number of particles does not change but their size increases. The critical radius of the nuclei increases with the increase of the annealing temperature (decreasing oversaturation). Moreover, the mean radius of the particles in the nucleation stage grows as a square root of the duration of annealing. A cubic root dependence of mean size on the annealing duration has been observed in the recondensation stage. Thus, the size of nanoparticles grown during the diffusion-controlled phase decomposition of oversaturated solid solutions is varied by controlling the temperature and/or the duration of heat treatment.

In operation 930, a metal plug can be formed on the retentive catalyst layer to fill the opening. Since retentive catalyst layer 1040 acts as a seeding layer, it is not removed, as shown in FIG. 10B. A deposition process can be performed to fill a metal material, such as Co, W, and Ru, into opening 690 to form a metal layer 1065, as shown in FIG. 10C. A subsequent CMP process can be performed to etch back the metal layer 1065 and remove portions of Gr film 650 and retentive seeding layer 1040 located outside of opening 940. The top surfaces of ILD 630, retentive seeding layer 1040, Gr film 650, and metal layer 1065 can be substantially coplanarized. The remaining portions of retentive seeding layer 1040 and metal layer 1065 inside opening 965 can form metal plug 1060, as shown in FIG. 10D.

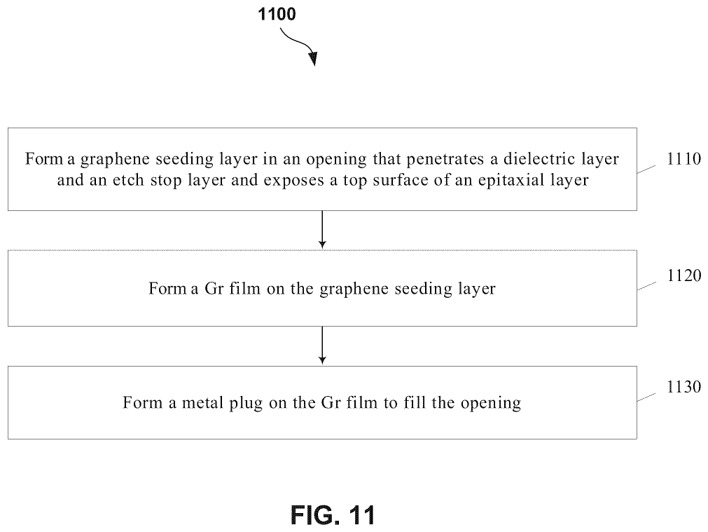

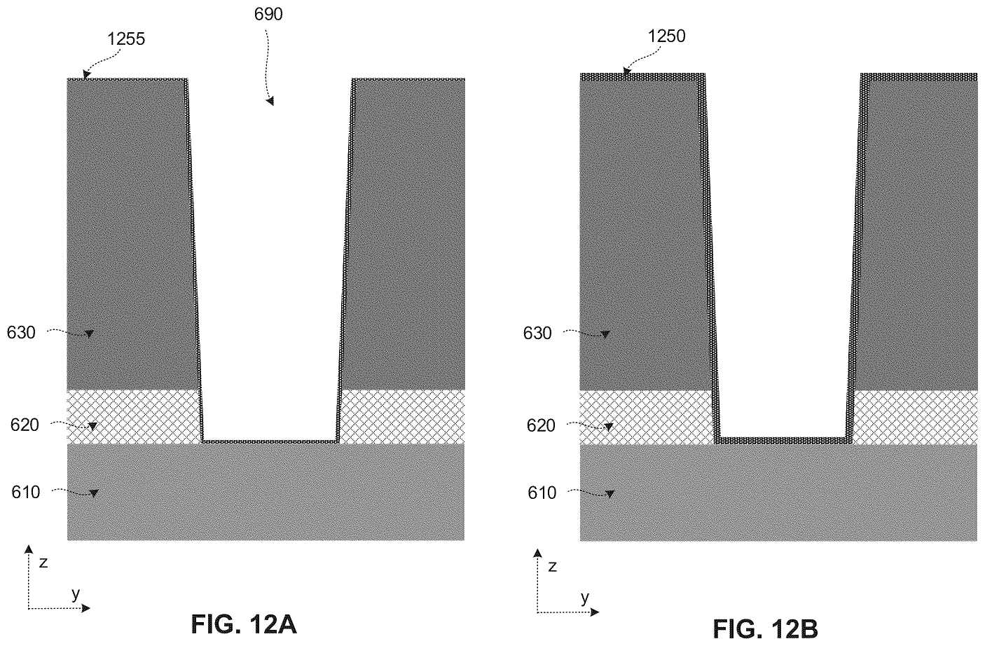

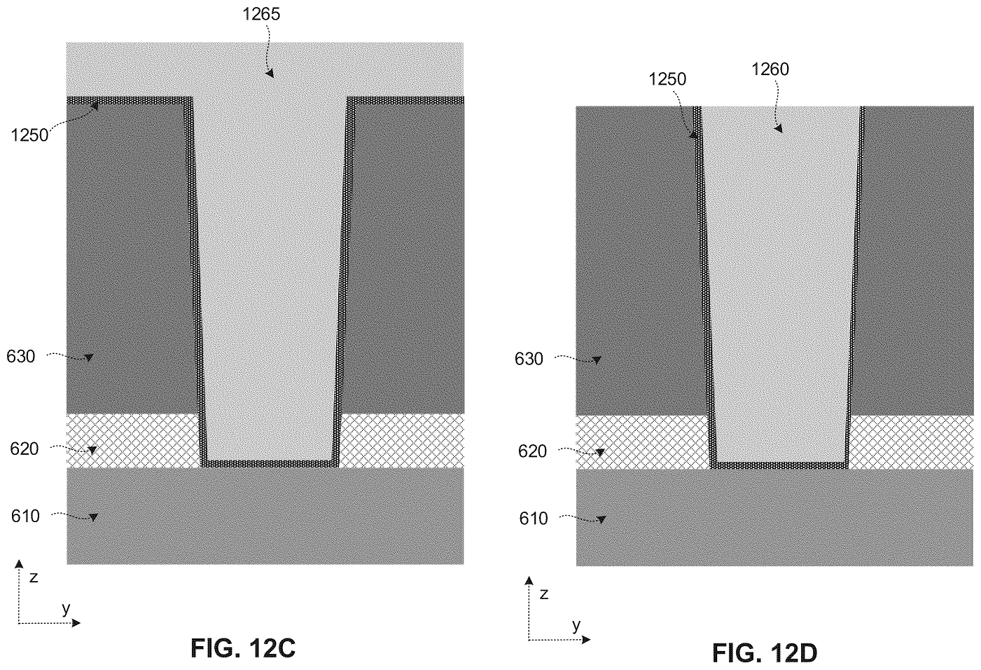

FIG. 11 is a flow diagram of another exemplary method 1100 for inserting a Gr film for a contact in a finFET, in accordance with some embodiments of the present disclosure. FIGS. 12A-12D illustrate schematic cross-sectional views of a portion of an exemplary finFET at certain fabricating stages of the method shown in FIG. 11, according to some embodiments of the present disclosure. Method 1100 does not produce completed finFET 100. Accordingly, it is understood that the operations shown in FIG. 11 are not exhaustive and that other operations can be performed before, after, or between any of the illustrated operations, and that some other processes may only be briefly described herein.

In operation 1110, a graphene seeding layer can be formed in an opening that penetrates a dielectric layer and an etch stop layer and exposes a top surface of an epitaxial layer. The graphene seeding layer can be used as a seed for graphene growth in a subsequent process.

Similar to method 500, in some embodiments, before operation 1110, EPI 610 can be epitaxially grown on a semiconductor material, ESL 620 can be formed on a top surface of EPI 610, ILD 630 can be formed on ESL 620, and opening 690 can be formed in ESL 620 and ILD 630 to expose a top surface of EPI 610.

In operation 1110, a graphene seeding layer 1255 can be formed to cover the bottom surface and sidewalls of opening 690. In some embodiments, graphene seeding layer 1255 can be formed by a gas phase synthesis process or a spin coating process by using 1,2,3,4-tetraphenylnaphthalene (TPN), Pyrene, or Benzene as the carbon source.

In the gas phase synthesis process, a thin Gr film can be synthesized by sending an aerosol consisting of argon gas and liquid ethanol droplets into an atmospheric-pressured, microwave-generated argon plasma field. The ethanol droplets can be evaporated and dissociated in the plasma to form a thin Gr film that is clean and highly ordered with few lattice imperfections and oxygen functionalities, which can have improved seed characteristics for subsequent graphene growth.

The spin coating process can include four stages: deposition, spin up, spin off, and evaporation. In the deposition stage, an aqueous dispersion of functionalized graphene solution can be deposited on the coated surface and then spun up and spun off occur in sequence while the evaporation stage occurs throughout the process. The applied solution on the turntable is distributed via centrifugal force. A high spinning speed results in thinning of the graphene layer. This stage is followed by drying off the graphene layer. Uniform evaporation of the solvent is possible because of rapid rotation. High volatile components are removed due to evaporation or drying and the low volatile carbon atoms remain on the surface. Thickness of the graphene layer is controlled by the viscosity of the coating solution and the speed of rotation.

In operation 1120, a Gr film can be formed on the graphene seeding layer. In some embodiments, any suitable method of activation and graphene growth, such as an ultraviolet (UV) cure, laser treatment, and thermal anneal, can be applied to the graphene seeding layer 1255 deposited from graphene dissolved in solution at operation 1110 to form Gr film 1250, as shown in FIG. 12B.

In some embodiments, a heat treatment may be performed in an inert atmosphere of argon, nitrogen, or helium for solvent removal. For example, in a UV curing process, graphene seeding layer 1255 can be irradiated by high-intensity ultraviolet light to rapidly cure the graphene atoms. As another example, a pulsed laser or a continuous wave laser source having a wavelength and intensity to heat graphene seeding layer 1255 can be used in a laser treatment for activation and graphene growth. As yet another example, a thermal activation annealing process at an annealing temperature in a range from about 380° C. to about 450° C. (e.g., about 400° C.) can be performed to drive precipitation and growth of carbon atoms.

In operation 1130, a metal plug can be formed on the Gr film to fill the opening. A deposition process can be performed to fill a metal material, such as Co, W, and Ru, into opening 690 to form metal layer 1265, as shown in FIG. 12C. A subsequent CMP process can be performed to etch back metal layer 1265 and remove portions of Gr film 1250 located outside of opening 690. The top surfaces of ILD 630, Gr film 1250, and metal layer 1265 can be substantially coplanarized. The remaining portion of the metal layer inside opening 690 can form metal plug 1260, as shown in FIG. 12D.

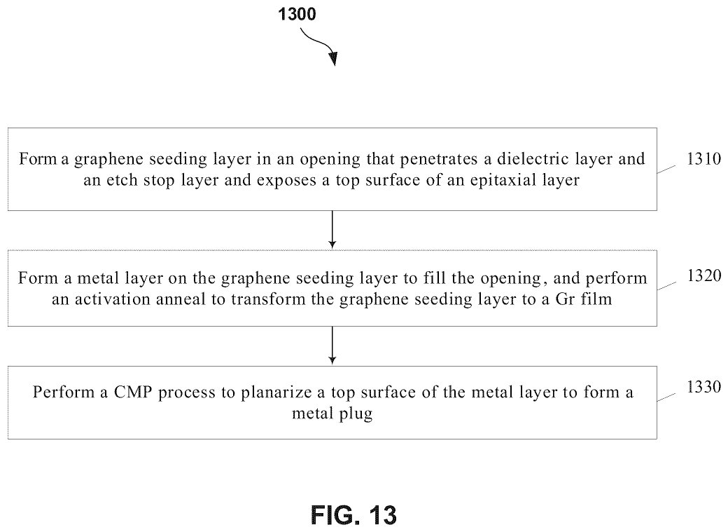

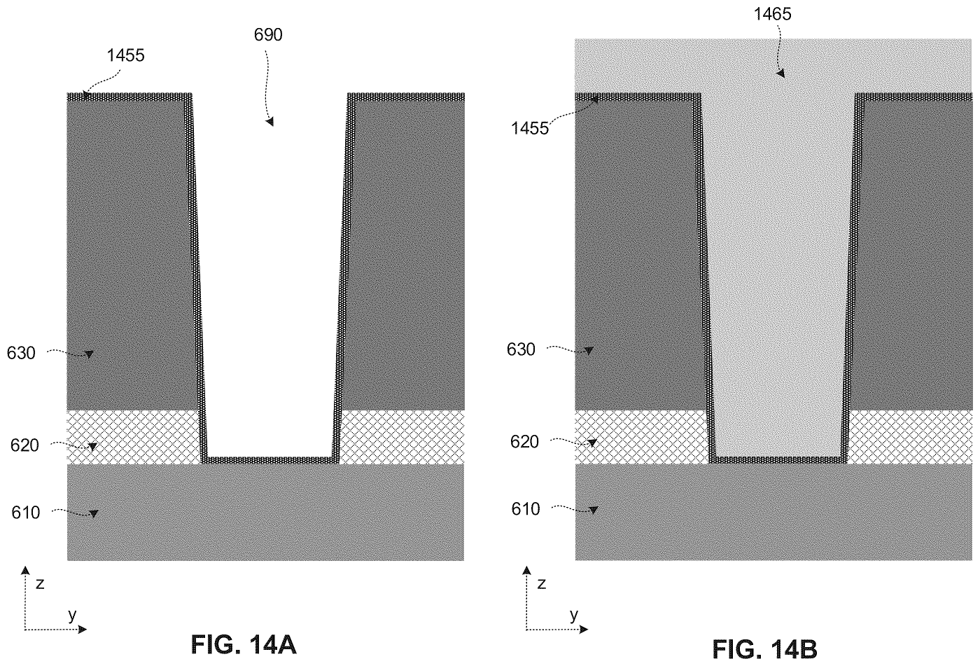

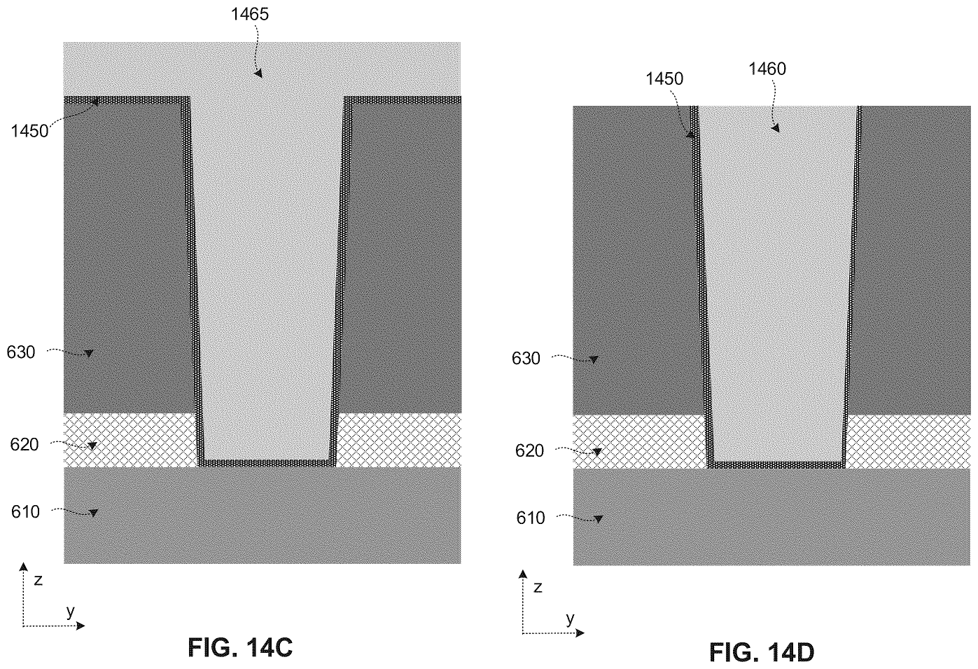

FIG. 13 is a flow diagram of another exemplary method 1300 for inserting a Gr film for a contact in a finFET, in accordance with some embodiments of the present disclosure. FIGS. 14A-14D illustrate schematic cross-sectional views of a portion of an exemplary finFET at certain fabricating stages of the method shown in FIG. 13, according to some embodiments of the present disclosure. Method 1300 does not produce completed finFET 100. Accordingly, it is understood that the operations shown in FIG. 13 are not exhaustive and that other operations can be performed before, after, or between any of the illustrated operations, and that some other processes may only be briefly described herein.

In operation 1310, a graphene seeding layer can be deposited in an opening that penetrates a dielectric layer and an etch stop layer and exposes a top surface of an epitaxial layer. The graphene seeding layer can be used as a seed for graphene growth in a subsequent process.

Similar to method 500, in some embodiments, before operation 1310, EPI 610 can be epitaxially grown on a semiconductor material, ESL 620 can be formed on a top surface of EPI 610, ILD 630 can be formed on ESL 620, and opening 690 can be formed in ESL 620 and ILD 630 to expose a top surface of EPI 610.

Similar to operation 1110, in operation 1310, a graphene seeding layer 1455 can be formed to cover the bottom surface and sidewalls of opening 690. In some embodiments, graphene seeding layer 1455 can be formed by a gas phase synthesis process or a spin coating process by using TPN, Pyrene, or Benzene as the carbon source.

In operation 1320, a metal layer can be formed on the graphene seeding layer to fill the opening, and an activation anneal process can be performed to transform the graphene seeding layer to a Gr film. For example, a deposition process can be performed to fill a metal material, such as Co, W, and Ru, into opening 690 to form metal layer 1465, as shown in FIG. 14B. A subsequent activation anneal process at an annealing temperature in a range from about 380° C. to about 450° C. (e.g., about 400° C.) in Ar or in vacuum can be performed to drive precipitation and growth of carbon atoms of graphene seeding layer 1455. Gr film 1450 can be formed at the interfaces between metal layer 1465 and EPI 610/ESL 620/ILD 630, as shown in FIG. 14C.

In operation 1330, a CMP process can be performed to planarize a top surface of the metal layer to form a metal plug. As shown in FIG. 14D, a CMP process can be performed to etch back metal layer 1465 and remove portions of Gr film 1450 located outside of opening 690. The top surfaces of ILD 630, Gr film 1450, and metal plug 1460 can be substantially coplanarized.

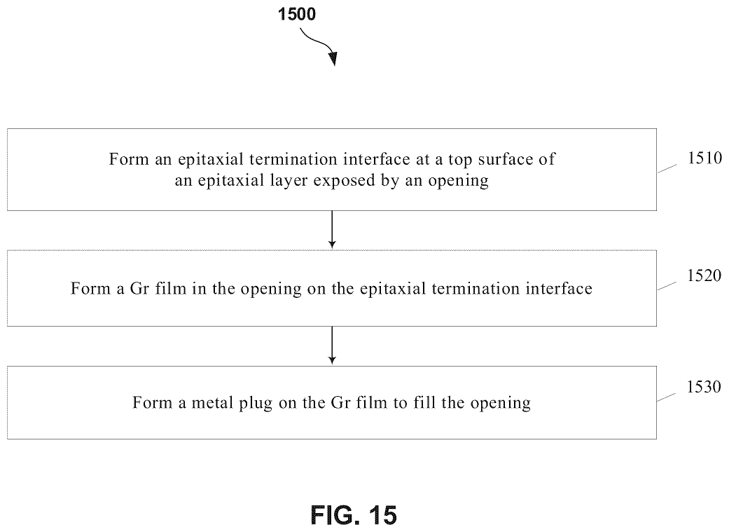

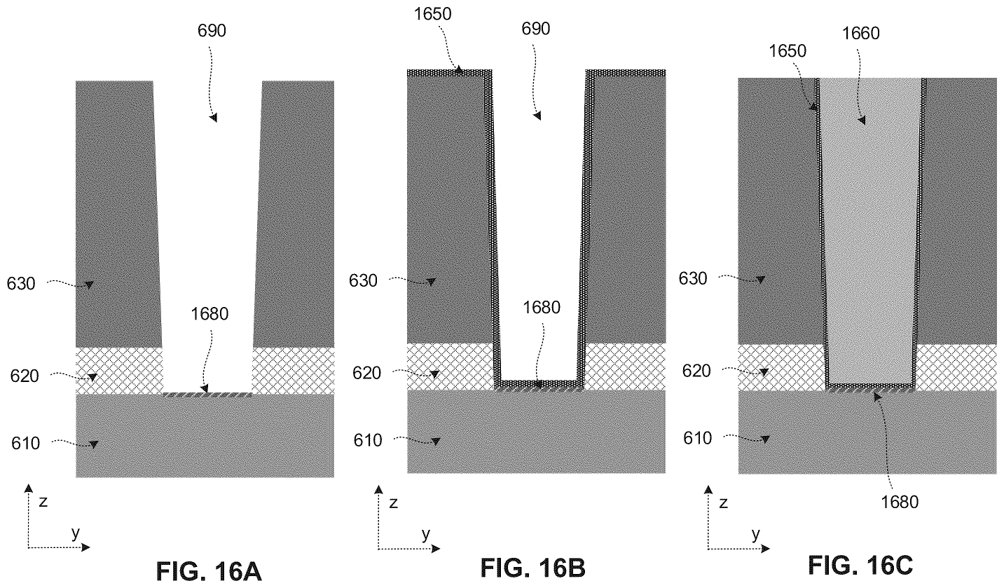

FIG. 15 is a flow diagram of another exemplary method 1500 for inserting a Gr film for a contact in a finFET, in accordance with some embodiments of the present disclosure. FIGS. 16A-16C illustrate schematic cross-sectional views of a portion of an exemplary finFET at certain fabricating stages of the method shown in FIG. 15, according to some embodiments of the present disclosure. Method 1500 does not produce completed finFET 100. Accordingly, it is understood that the operations shown in FIG. 15 are not exhaustive and that other operations can be performed before, after, or between any of the illustrated operations, and that some other processes may only be briefly described herein.

In operation 1510, a surface treatment can be performed to a bottom surface of an opening that penetrates a dielectric layer and an etch stop layer to form an epitaxial termination interface at a top surface of an epitaxial layer exposed by the opening.

Similar to method 500, in some embodiments, before operation 1510, EPI 610 can be epitaxially grown on a semiconductor material, ESL 620 can be formed on a top surface of EPI 610, ILD 630 can be formed on ESL 620, and opening 690 can be formed in ESL 620 and ILD 630 to expose a top surface of EPI 610.

A surface treatment process can be used to treat the top surface of EPI 610 that is exposed by opening 690 to form an epitaxial termination interface 1680 at the bottom of opening 690 and on EPI 610, as shown in FIG. 16A. In some embodiments, the top surface of EPI 610 may treated with non-deposited plasma products. The treated surface nucleates polysilicon and poly-SiGe. The surface treatment provides surface moieties susceptible to a subsequent deposition reaction or susceptible to further surface treatment prior to deposition. By changing the top surface of EPI 610 to an epitaxial termination interface 1680, the SBH between EPI 610 and subsequently formed metal plug can be reduced.

In operation 1520, a Gr film can be formed in the opening on the epitaxial termination interface. In some embodiments, a graphene seeding layer can be formed to cover the bottom surface and sidewalls of opening 690. In some embodiments, the graphene seeding layer can be formed by a gas phase synthesis process or a spin coating process by using TPN, Pyrene, or Benzene as the carbon source. A subsequent heat treatment, such as a UV curing process, may be performed to drive precipitation and growth of carbon atoms of the graphene seeding layer to form Gr film 1650, as shown in FIG. 16B.

In operation 1530, a metal plug can be formed on the Gr film to fill the opening. A deposition process can be performed to fill a metal material, such as Co, W, and Ru, into opening 690 to form a metal layer. A subsequent CMP process can be performed to etch back the metal layer and remove portions of Gr film 1650 located outside of opening 690. The top surfaces of ILD 630, Gr film 1650, and metal plug 1660 can be substantially coplanarized. As shown in FIG. 16C, a portion of Gr film 1650 and the epitaxial termination interface 1680 can be located between metal plug 1660 and EPI 610.

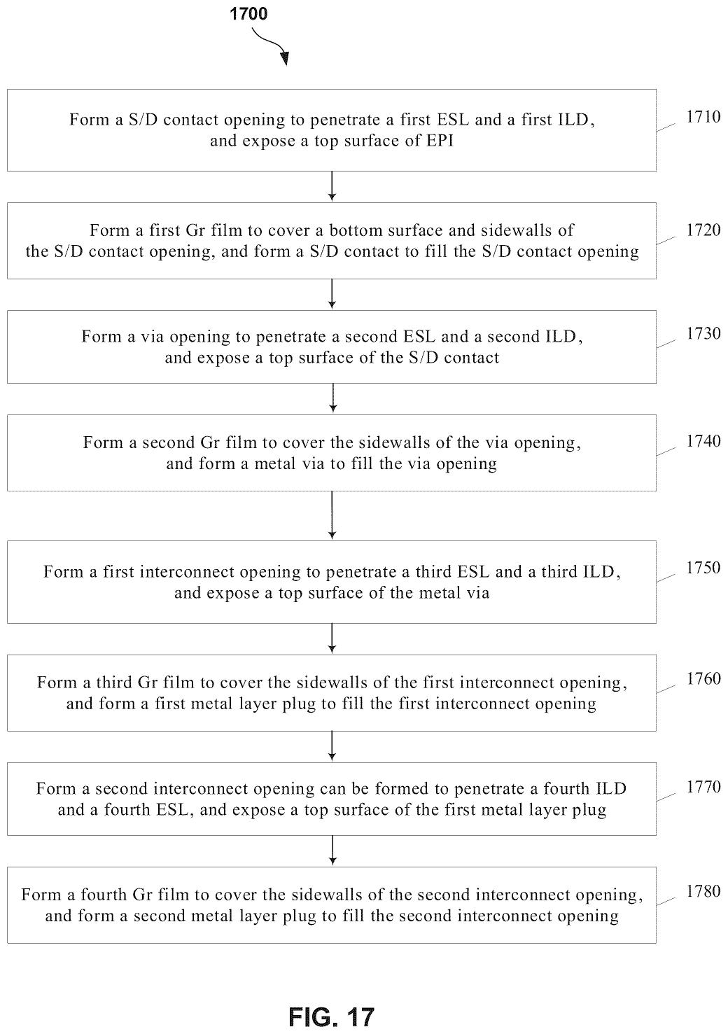

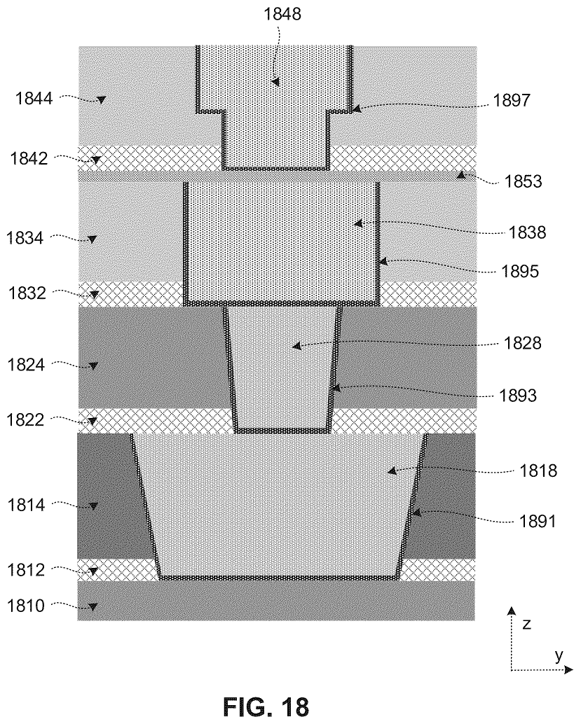

FIG. 17 is a flow diagram of an exemplary method 1700 for forming an interconnect structure 1800 of a finFET, in accordance with some embodiments of the present disclosure. FIG. 18 illustrates a schematic cross-sectional view of an exemplary interconnect structure of a finFET formed by the method shown in FIG. 17, according to some embodiments of the present disclosure. Operations shown in FIG. 17 are not exhaustive and that other operations can be performed before, after, or between any of the illustrated operations, and that some other processes may only be briefly described herein.

In operation 1710, an epitaxial layer EPI 1810, a first ESL 1812, and a first ILD 1814 can be stacked in a vertical direction, and a S/D contact opening can be formed to penetrate first ESL 1812 and first ILD 1814 and expose a top surface of EPI 1810.

In some embodiments, EPI 1810 can be epitaxially grown on a semiconductor material, first ESL 1812 can be formed on a top surface of EPI 1810, and first ILD 1814 can be a high-k dielectric layer formed on first ESL 1812. In some embodiments, a S/D contact opening can be formed to penetrate first ESL 1812 and first ILD 1814 to expose a top surface of EPI 1810. The S/D contact opening can be formed by any suitable patterning process. For example, a lithography process can be performed to pattern a mask for the opening and one or more subsequent wet or dry etching processes can be performed to etch a portion of first ESL 1812 and first ILD 1814 exposed by the patterned mask. A cleaning process, such as an ashing process and a strip process, can be performed after the etching to clean the sidewalls and bottom surface of the S/D contact opening.

In operation 1720, a first Gr film 1891 can be formed to cover the bottom surface and sidewalls of the S/D contact opening, and S/D contact 1818 can be formed to fill the S/D contact opening. A CMP process can be performed to coplanarize top surfaces of first ILD 1814, first Gr film 1891, and S/D contact 1818.

In some embodiments, first Gr film 1891 and S/D contact 1818 can be formed by method 500 described above in connection with FIGS. 5 and 6A-6D. In such embodiments, a material of the sacrificial catalyst layer can be Ni, etc., and a material of the S/D contact 1818 can be Mo, Co, Ru, W, etc. In some embodiments, first Gr film 1891 and S/D contact 1818 can be formed by method 700 described above in connection with FIGS. 7 and 8A-8C. In such embodiments, a material of the retentive catalyst layer and S/D contact 1818 can be Co, Ru, etc. In some embodiments, first Gr film 1891 and S/D contact 1818 can be formed by method 900 described above in connection with FIGS. 9 and 10A-10C. In such embodiments, a material of the retentive catalyst layer can be Ru, etc., and a material of S/D contact 1818 can be Co, W, Mo, etc.

In operation 1730, a second ESL 1822 can be formed on first ILD 1814 and S/D contact 1818, a second ILD 1824 can be a high-k dielectric layer formed on second ESL 1822, and a via opening can be formed to penetrate second ESL 1822 and second ILD 1824 and expose a top surface of S/D contact 1818. The via opening can be formed by any suitable patterning process.

In operation 1740, a second Gr film 1893 can be formed to cover the sidewalls of the via opening, and a metal via 1828 can be formed to fill the via opening. A CMP process can be performed to coplanarize top surfaces of second ILD 1824, second Gr film 1893, and metal via 1828. In some embodiments, S/D contact 1818 and metal via 1828 may have the same metal material.

In some embodiments, second Gr film 1893 and metal via 1828 can be formed by method 500 described above in connection with FIGS. 5 and 6A-6D. In such embodiments, a material of the sacrificial catalyst layer can be Cu or Ni, and a material of metal via 1828 can be Mo, Co, Ru or W. In some embodiments, second Gr film 1893 and metal via 1828 can be formed by method 700 described above in connection with FIGS. 7 and 8A-8C. In such embodiments, a material of retentive catalyst layer and metal via 1828 can be Co or Ru. In some embodiments, second Gr film 1893 and metal via 1828 can be formed by method 900 described above in connection with FIGS. 9 and 10A-10C. In such embodiments, a material of the retentive catalyst layer is Ru, and a material of metal via 1828 can be Co, W or Mo.

In operation 1750, a third ESL 1832 can be formed on second ILD 1824 and metal via 1828, a third ILD 1834 can be formed on third ESL 1832, and a first interconnect opening can be formed to penetrate third ESL 1832 and third ILD 1834 and expose a top surface of metal via 1828. The first interconnect opening can be formed by any suitable patterning process.

In operation 1760, a third Gr film 1895 can be formed to cover the sidewalls of the first interconnect opening, and a first metal layer plug 1838 can be formed to fill the first interconnect opening. A CMP process can be performed to coplanarize top surfaces of third ILD 1834, third Gr film 1895, and first metal layer plug 1838. In some embodiments, a material of first metal layer plug 1838 may be different from the material of S/D contact 1818 and metal via 1828.

In some embodiments, third Gr film 1895 and first metal layer plug 1838 can be formed by method 700 described above in connection with FIGS. 7 and 8A-8C. In such embodiments, a material of the retentive catalyst layer and first metal layer plug 1838 can be Cu. In some embodiments, third Gr film 1895 and first metal layer plug 1838 can be formed by method 900 described above in connection with FIGS. 9 and 10A-10C. In such embodiments, a material of the retentive catalyst layer is Ru, and a material of first metal layer plug 1838 can be Cu or Co.

In operation 1770, a fourth ESL 1842 can be formed on third ILD 1834 and first metal layer plug 1828, a fourth ILD 1844 can be formed on fourth ESL 1842, and a second interconnect opening can be formed to penetrate fourth ILD 1844 and fourth ESL 1842 and expose a top surface of first metal layer plug 1838. The second interconnect opening can be formed by any suitable patterning process and can include a capping region with a reduced width along a y-direction.

In operation 1780, a fourth Gr film 1897 can be formed to cover the sidewalls and corners of the second interconnect opening, and a second metal layer plug 1848 can be formed to fill the second interconnect opening. A CMP process can be performed to coplanarize top surfaces of fourth ILD 1844, fourth Gr film 1897, and second metal layer plug 1848. In some embodiments, first metal layer plug 1838 and second metal layer plug 1848 may have the same metal material.

In some embodiments, fourth Gr film 1897 and second metal layer plug 1848 can be formed by method 700 described above in connection with FIGS. 7 and 8A-8C. In such embodiments, a material of the retentive catalyst layer and second metal layer plug 1848 can be Cu. In some embodiments, fourth Gr film 1897 and second metal layer plug 1848 can be formed by method 900 described above in connection with FIGS. 9 and 10A-10C. In such embodiments, a material of the retentive catalyst layer is Ru, and a material of second metal layer plug 1848 can be Cu or Co.

Method 1700 (corresponding to FIGS. 17 and 18) uses finFET interconnect structure 1800 with two metal layers as an example. Method 1700 can be extended to insert Gr films to a higher number of metal layer contacts/interconnects.

The present disclosure describes exemplary epitaxial low resistance contacts and damascene interconnects that include a Gr film in fin structures of finFETs. This disclosure also provides fabricating methods for inserting Gr films for S/D contacts, S/D contacts, and metal vias in MEOL and/or in BEOL to achieve ultra-low contact resistivity, thinner liner and barrier, and decreased elastic scattering.

One aspect of the present disclosure provides a semiconductor device including a substrate and a fin structure on the substrate. The fin structure includes an epitaxial region. The semiconductor device can further include an etch stop layer on the epitaxial region, and an interlayer dielectric layer on the etch stop layer. The semiconductor device can further include a metal contact, above the epitaxial region, formed through the etch stop layer and the interlayer dielectric layer, and a graphene film at interfaces between the metal contact and each of the epitaxial region, the etch stop layer, and the interlayer dielectric layer.

In some embodiments, the fin structure is a merged fin structure, and the epitaxial region is a merged epitaxial region. In some embodiments, the semiconductor device can further include an other fin structure, on the substrate, including an other epitaxial region; a barrier layer on a top surface of the other epitaxial region; an other metal contact above the barrier layer; and a liner layer at an interface between the other metal contact and the barrier layer. In some embodiments, the epitaxial region is an n-type epitaxial region, and the other epitaxial region is a p-type epitaxial region. In some embodiments, the epitaxial region is a p-type epitaxial region, and the other epitaxial region is an n-type epitaxial region. In some embodiments, the semiconductor device can further include an other fin structure, on the substrate, including an other epitaxial region having an opposite type from that of the epitaxial region; and an other graphene film at an interface between the other metal contact and the other interlayer dielectric layer. In some embodiments, a thickness of the graphene film is between 0.02 nm and 5 nm. In some embodiments, the semiconductor device can further include a via on a top surface of the metal contact, and an other graphene film on a sidewall of the via. In some embodiments, the semiconductor device can further include a metal plug on a top surface of the via; and a third graphene film on a sidewall of the metal plug. In some embodiments, the semiconductor device can further include an other metal plug on a top surface of the metal plug, and an other graphene film on a sidewall of the other metal plug.

Another aspect of the present disclosure provides a method of forming a semiconductor device, including: forming a fin structure with an epitaxial layer; forming a catalyst layer in an opening that exposes a top surface of the epitaxial layer; forming a graphene film at an interface between the catalyst layer and the epitaxial layer; and forming a metal plug on the graphene film to fill the opening. In some embodiments, the method further includes prior to forming the metal plug, removing the catalyst layer. In some embodiments, forming the catalyst layer includes depositing a first metal, and forming the metal plug includes depositing a second metal different from the first metal. In some embodiments, forming the catalyst layer includes depositing a first metal, and forming the metal plug includes depositing the first metal on the catalyst layer, where the catalyst layer is used as a seeding layer. In some embodiments, forming the catalyst layer includes depositing a first metal, and forming the metal plug includes depositing a second metal on the catalyst layer, where the catalyst layer is used as a seeding layer and the second metal is different from the first metal.

Another aspect of the present disclosure provides a method of forming a semiconductor device, including: forming a fin structure with an epitaxial layer; forming a graphene seeding layer in an opening that exposes a top surface of the epitaxial layer; forming a graphene film by heating the graphene seeding layer to drive precipitation and growth of carbon atoms in the graphene seeding layer; and forming a metal plug on the graphene film to fill the opening. In some embodiments, forming the graphene seeding layer includes using 1,2,3,4-tetraphenylnaphthalene, Pyrene, or Benzene as a carbon source. In some embodiments, forming the graphene film includes heating the graphene seeding layer by one of an ultraviolet curing process, a laser treatment process, and a thermal anneal process. In some embodiments, forming the metal plug includes depositing a metal in the opening; and performing an activation annealing process at a temperature between about 380° C. and about 450° C. in argon or a vacuum. In some embodiments, the method further includes: prior to forming the graphene seeding layer, forming an epitaxial termination interface by treating the top surface of the epitaxial layer.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the subjoined claims.

What is claimed is:

1. A semiconductor device, comprising:
a substrate;
a fin structure, on the substrate, comprising an epitaxial region;
an etch stop layer on the epitaxial region;
an interlayer dielectric layer on the etch stop layer;
a metal contact formed through the etch stop layer and the interlayer dielectric layer and disposed on the epitaxial region; and
a graphene film at interfaces between the metal contact and each of the epitaxial region, the etch stop layer, and the interlayer dielectric layer.

2. The semiconductor device of claim 1, wherein:
the fin structure is a merged fin structure; and
the epitaxial region is a merged epitaxial region.

3. The semiconductor device of claim 1, further comprising:
another fin structure, on the substrate, comprising another epitaxial region;
a barrier layer on a top surface of the other epitaxial region;
another metal contact disposed on the barrier layer; and
a liner layer at an interface between the other metal contact and the barrier layer.

4. The semiconductor device of claim 3, wherein:
the epitaxial region is an n-type epitaxial region; and
the other epitaxial region is a p-type epitaxial region.

5. The semiconductor device of claim 3, wherein:
the epitaxial region is a p-type epitaxial region; and
the other epitaxial region is an n-type epitaxial region.

6. The semiconductor device of claim 1, further comprising:
another fin structure, on the substrate, comprising another epitaxial region having an opposite type from that of the epitaxial region; and
another graphene film disposed on the other epitaxial layer.

7. The semiconductor device of claim 1, wherein a thickness of the graphene film is between about 0.3 nm and about 5 nm.

8. The semiconductor device of claim 1, further comprising:
a via on a top surface of the metal contact; and
a second graphene film on a sidewall of the via.

9. The semiconductor device of claim 8, further comprising:
a metal plug on a top surface of the via; and
a third graphene film on a sidewall of the metal plug.

10. The semiconductor device of claim 1, wherein a top surface of the graphene film is substantially coplanar with a top surface of the metal contact.

11. A semiconductor device, comprising:
a fin structure with an epitaxial layer;
a metal plug on the epitaxial layer; and
a graphene layer at an interface between the epitaxial layer and the metal plug.

12. The semiconductor device of claim 11, further comprising a dielectric layer surrounding the graphene layer and in contact with the graphene layer.

13. The semiconductor device of claim 11, further comprising an etch stop layer surrounding the graphene layer and in contact with the graphene layer.

14. The semiconductor device of claim 11, wherein the epitaxial region is a merged epitaxial region comprising:
a first epitaxial region formed on a first sub-region disposed on a first portion of the substrate; and
a second epitaxial region formed on a second sub-region disposed on a second portion of the substrate.

15. The semiconductor device of claim 14, wherein the first sub-region has a first dopant concentration and the second sub-region has a second dopant concentration different from the first dopant concentration.

16. A semiconductor device, comprising:
a first fin structure with a first epitaxial layer;
a second fin structure with a second epitaxial layer in contact with the first epitaxial layer; and
a contact structure disposed on the first and second epitaxial layers, wherein the contact structure comprises:
a graphene layer in contact with the first and second epitaxial layers; and
a conductive layer in contact with a bottom surface and sidewall surfaces of the graphene layer.

17. The semiconductor device of claim 16, wherein the graphene layer comprises a monolayer of carbon atoms.

18. The semiconductor device of claim 16, further comprising an etch stop layer disposed on the first and second epitaxial layers.

19. The semiconductor device of claim 18, further comprising a dielectric layer disposed on the etch stop layer.

20. The semiconductor device of claim 19, wherein the graphene layer is in contact with the etch stop layer and the dielectric layer.
